(19) United States
(12) Patent Application Publication
(10) Pub. No.: US 2008/0314444 A1
(43) Pub. Date: Dec. 25, 2008

(54) ELECTRICALLY CONDUCTIVE PASTE AND SOLAR CELL

(75) Inventor: Yoshihiro Kawaguchi, Kyoto-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: MURATA MANUFACTURING CO., LTD., Nagaokakyo-Shi (JP)

(21) Appl. No.: 12/206,215

(22) Filed: Sep. 8, 2008

Related U.S. Application Data
(63) Continuation of application No. PCT/JP2007/051769, filed on Feb. 2, 2007.

(30) Foreign Application Priority Data
Mar. 7, 2006 (JP) 2006-060531
Aug. 31, 2006 (JP) 2006-235524

(51) Int. Cl. H01B 1/22; H01L 31/0216

(52) U.S. Cl. 136/256; 252/501.1

(57) ABSTRACT

An electrically conductive paste which can be formed into an electrode by being fired at relatively low temperatures, which exhibits excellent adhesion strength between a light-receiving surface electrode and a semiconductor substrate, and which can satisfactorily reduce the contact resistance between the two, is provided. The electrically conductive paste used as a material for a light-receiving surface electrode of a solar cell, includes a Ag powder, an organic vehicle, and glass frit, wherein the softening point of the above-described glass frit is 570° C. 760° C., and the glass frit contains B₂O₃ and SiO₂ in such a way that the ratio, B₂O₃/SiO₂, becomes 0.3 or less on a molar ratio basis and the first contains 0 to less than 20.0 percent by mole of Bi₂O₃.

This is a continuation of application Serial No. PCT/JP2007/051769, filed Feb. 2, 2007.

### TECHNICAL FIELD

The present invention relates to an electrically conductive paste serving as an electrically conductive material used for a light-receiving surface electrode of a solar cell. In particular, the present invention relates to an electrically conductive paste containing a Ag powder and silicate glass based glass frit and a solar cell provided with a light-receiving surface electrode by using the electrically conductive paste.

### BACKGROUND ART

In a solar cell including a Si semiconductor, a semiconductor substrate provided with an n-type Si based semiconductor layer on an upper surface of a p-type Si based semiconductor layer has been used previously. A light-receiving surface electrode is disposed on one surface of this semiconductor substrate, and a reverse surface electrode is disposed on the other surface.

The light-receiving surface electrode is has been formed by baking an electrically conductive paste containing a metal powder. As for such an electrically conductive paste, for example, an electrically conductive paste containing a Ag powder, glass frit, and an organic vehicle is disclosed in Patent Document 1 described below.

The glass frit has the property of enhancing the adhesion strength between the light-receiving surface electrode obtained by firing the electrically conductive paste and the semiconductor substrate. It is believed to be preferable that the glass powder have a low softening point be used as the glass frit in order to obtain high adhesion strength. Patent Document 1 discloses that B—Pb—O based, B—Si—Pb—O based, B—Si—Bi—Pb—O based, or B—Si—Zn—O based glass frit or the like, can be appropriately used as such a glass powder. The specific examples thereof are those in which Pb—B—Si—O based glass frit and B—Si—Zn—O based glass frit are used.

Patent Document 1: Japanese Unexamined Patent Application Publication No. 2001-118425

### DISCLOSURE OF INVENTION

A glass frit containing Pb has a relatively low melting point. Therefore, even when firing is conducted by heating at low temperatures, the adhesion strength between a semiconductor substrate and a light-receiving surface electrode can be enhanced effectively. However, since Pb is a hazardous substance, it has been required that a alternative material is used.

As for the glass frit, Patent Document 1 describes B—Si—Zn—O based glass frit as well as Pb—B—Si—O based glass frit containing Pb, as described above. However, the description related to the B—Si—Zn—O based glass frit in Patent Document 1 is merely that described above, and no specific composition of this glass frit is shown.

In the case where a light-receiving surface electrode of a solar cell is formed by using an electrically conductive paste, as described above, an electrically conductive paste which can satisfactorily enhance the adhesion strength between a semiconductor electrode and a light-receiving surface electrode even when firing is conducted at relatively low temperatures and which does not contain a hazardous material, e.g., Pb, has been required intensely.

In consideration of the present circumstances of the above-described related art, it is an object of the present invention to provide an electrically conductive paste which can effectively enhance the adhesion strength between a light-receiving surface electrode and a semiconductor substrate and furthermore reduce the contact resistance between the two even when firing is conducted at relatively low temperatures and which does not contain Pb hazardous to the environment and a solar cell-in which a light-receiving surface electrode is provided by using the electrically conductive paste.

According to a first embodiment of the present invention, an electrically conductive paste used as a material for a light-receiving surface electrode of a solar cell is provided, the electrically conductive paste being characterized by including a Ag powder, an organic vehicle, and glass frit, wherein the softening point of the above-described glass frit is 570° C. to 760° C. and the glass frit contains B₂O₃ and SiO₂ in such a way that the ratio thereof, B₂O₃/SiO₂, is 0.3 or less on a molar basis and which does not contain Bi₂O₃.

According to a second embodiment of the present invention, an electrically conductive paste used as a material for a light-receiving surface electrode of a solar cell is provided, the electrically conductive paste being characterized by including a Ag powder, an organic vehicle, and glass frit, wherein the softening point of the above-described glass frit is 570° C. to 760° C. and the glass frit contains B₂O₃ and SiO₂ in such a way that the ratio of them, B₂O₃/SiO₂, is 0.3 or less on a molar basis, and which contains less than 20.0 percent by mole of Bi₂O₃.

That is, the present invention (hereafter, the first embodiment and the second embodiment are appropriately collectively called the present invention) is characterized in that the Ag powder, the organic vehicle, and the glass frit are included, the softening point of the glass frit is within the range of 570° C. to 760° C., and the glass frit contains SiO₂ and, if necessary, contains Bi₂O₃, while the ratio B₂O₃/SiO₂ is specified to be 0.3 or less on a molar ratio basis.

Preferably, the above-described glass frit further contains Al₂O₃, TiO₂, and CuO at ratios of Al₂O₃ of 15 percent by mole or less, TiO₂ of 0 to 10 percent by mole, and CuO of 0 to 15 percent by mole.

In another specific aspect of the electrically conductive paste according to the present invention, at least one type of additive selected from ZnO, TiO₂, and ZrO₂ is further included besides the above-described glass frit.

In another specific aspect of the electrically conductive paste according to the present invention, at least one type of metal selected from Zn, Bi, and Ti or a compound of the metal in the form of a resinate is further included as an additive besides the above-described glass frit.

A solar cell according to the present invention is characterized by including a semiconductor substrate, a light-receiving surface electrode disposed on one surface of the semiconductor substrate, and a reverse surface electrode disposed on the other surface, wherein the above-described light-receiving surface electrode is composed of an electrically conductive film formed from the electrically conductive paste constructed according to the present invention.

### ADVANTAGES

In the electrically conductive paste according to the first embodiment, the Ag powder is used as an electrically conductive metal powder, and the glass frit having a softening point of 570° C. to 760° C. is used as the glass frit. Furthermore, the glass frit contains B₂O₃ and SiO₂ in such a way that the ratio, B₂O₃/SiO₂, becomes 0.3 or less on a molar basis and the first does not contain Bi₂O₃. Therefore, as is clear from an embodiment according to the present invention described later, even when firing is conducted at relatively low temperatures, a light-receiving surface electrode exhibiting excellent adhesion strength can be formed, and the contact resistance between the light-receiving surface electrode and the semiconductor layer is not increased significantly. In addition, since the glass frit does not contain Pb, which is hazardous to the environment, an electrically conductive paste exhibiting excellent environment resistance can be provided.

In the electrically conductive paste according to the second embodiment, the Ag powder is included as an electrically conductive metal powder, and glass frit having a softening point of 570° C. or higher, and 760° C. or lower is used as the glass frit. Furthermore, the glass frit contains B₂O₃ and SiO₂ in such a way that B₂O₃/SiO₂ becomes 0.3 or less on a molar basis and contains Bi₂O₃ at a ratio of less than 20.0 percent by mole. Therefore, as is clear from examples described later, firing can be conducted at low temperatures, and in the case where a light-receiving surface electrode is formed, the adhesion strength of the light-receiving surface electrode to a semiconductor layer can be enhanced effectively and the contact resistance between the two is not allowed to increase significantly. In addition, the glass frit does not contain Pb. Consequently, a solar cell exhibiting excellent reliability and excellent environment resistance characteristic can be provided.

The solar cell according to the present invention has the light-receiving surface electrode on one surface of the semiconductor substrate, and the reverse surface electrode on the other surface, wherein the light-receiving surface electrode is composed of an electrically conductive film formed by baking the electrically conductive paste according to the present invention. Therefore, the light-receiving surface electrode can be formed by baking at relatively low temperatures. Furthermore, the adhesion strength of the light-receiving surface electrode to the semiconductor substrate is at a satisfactory level. Moreover, the contact resistance at the interface between the two is not allowed to increase significantly. Consequently, it becomes possible to increase the reliability of the solar cell and reduce the cost. In addition, since the glass frit does not contain Pb, the environmental load can be reduced.

### BRIEF DESCRIPTION OF DRAWINGS

FIG. 1 is a partial cutaway front sectional view showing a solar cell according to an embodiment of the present invention.

FIG. 2 is a magnified partial plan view schematically showing two-dimensional shape of a light-receiving surface electrode of the solar cell, as shown in FIG. 1.

FIG. 3 is a schematic plan view showing a screen printing pattern used in formation of light-receiving surface electrodes in Examples and Comparative examples and a plurality of print portions included in the pattern.

### REFERENCE NUMERALS

1 solar cell
2 semiconductor substrate
2a p-type Si based semiconductor layer
2b n-type Si based semiconductor layer
3 light-receiving surface electrode
4 antireflection film
5 reverse surface electrode
6 terminal electrode

### BEST MODES FOR CARRYING OUT THE INVENTION

The present invention will be made clear below by describing specific embodiments of the present invention with reference to the drawings.

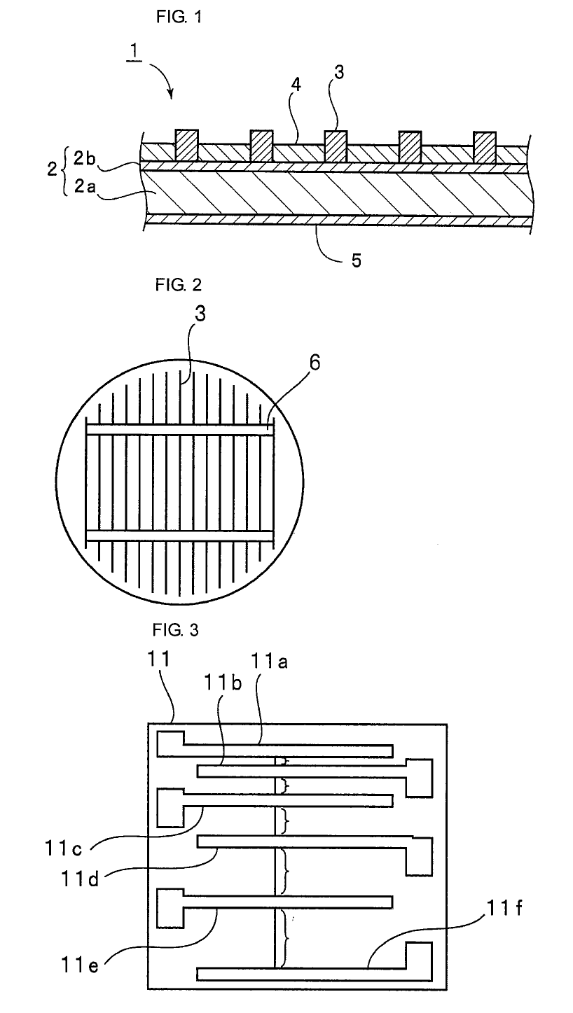

FIG. 1 is a partial cutaway front sectional view showing a solar cell according to an embodiment of the present invention. FIG. 2 is a magnified partial plan view schematically showing an electrode structure disposed on an upper surface thereof.

A solar cell 1 includes a semiconductor substrate 2. The semiconductor substrate 2 has a structure in which an n-type Si based semiconductor layer 2b is disposed on an upper surface of a p-type Si based semiconductor layer 2a. Such a semiconductor substrate 2 is obtained by diffusing impurities in one surface of a p-type Si based semiconductor substrate so as to form the n-type semiconductor layer 2b. However, the structure and the production method regarding the semiconductor substrate 2, are not specifically limited insofar as the n-type Si based semiconductor layer 2b is disposed on the upper surface of the p-type Si based semiconductor layer 2a.

A light-receiving surface electrode 3 is disposed on the side of the surface on which the n-type Si based semiconductor layer 2b is disposed, that is, the upper surface, of the semiconductor substrate 2. As is clear from the plan view shown in FIG. 2, the light-receiving surface electrode 3 has a structure in which a plurality of stripe-shaped electrode portions are disposed in parallel. Incidentally, one end of the light-receiving surface electrode is electrically connected to a terminal electrode 6. An antireflection film 4 is disposed in regions except the parts on which the light-receiving surface electrode 3 and the terminal electrode 6 are disposed.

On the other hand, a reverse surface electrode 5 is disposed on all of the surface on the lower surface side of the semiconductor substrate 2.

In the solar cell 1, the light-receiving surface electrode 3 is formed by applying and firing an electrically conductive paste according to an embodiment of the present invention. The electrically conductive paste and the light-receiving surface electrode 3 will be described in detail later.

The antireflection film 4 is formed from an appropriate insulating material, e.g., SiN, and is disposed to reduce reflection of light from the outside on the light-receiving surface side and promptly efficiently lead the light to the semiconductor layer 2. The material for constituting this antireflection film 4 is not limited to SiN, and other insulating materials, e.g., SiO₂ or TiO₂, may be used.

Furthermore, the reverse surface electrode 5 is disposed to take out electric power between the light-receiving surface electrode 3 and the reverse surface electrode 5. The material for forming this reverse surface electrode 5 is not specifically limited, and the reverse surface electrode 5 is obtained by applying and firing the same electrically conductive paste as that for the light-receiving surface electrode 3 or providing other electrode materials by appropriate methods.

The solar cell 1 is characterized in that the light-receiving surface electrode 3 includes a Ag powder, an organic vehicle, and glass frit, wherein the softening point of the glass frit is within the range of 570° C. to 760° C., and the glass frit has a composition in which the ratio B₂O₃/SiO₂ is 0.3 or less on a molar basis.

The Ag powder exhibits good electrical conductivity even in the case where firing is conducted in air. Therefore, in the present invention, the Ag powder is used as the electrically conductive metal powder of the electrically conductive paste. This Ag powder may be in the shape of a sphere or in the shape of a scale, but the shape thereof is not specifically limited. Furthermore, Ag powders in a plurality of shape types may be used in combination.

The average particle diameter of the Ag powder is not specifically limited. However, 0.1 to 15 μm is preferable. If the average particle diameter exceeds 15 μm, contact between the light-receiving surface electrode and the semiconductor substrate tends to become unsatisfactory.

The glass frit contained in the above-described electrically conductive paste is included in order to enhance the adhesion strength in application and baking of the electrically conductive paste.

Furthermore, if the softening point of the glass frit is too low, the viscosity of the glass in the firing of the electrically conductive paste, becomes too low, excess glass is accumulated at the interface between the light-receiving surface electrode and the semiconductor substrate and, as a result, the glass may hinder the contact between the two significantly. On the other hand, if the softening point of the glass frit is too high, the viscosity of the glass is not reduced significantly during firing of the electrically conductive paste. Consequently, the antireflection film is not removed satisfactorily, bonding between the light-receiving surface electrode and the semiconductor substrate becomes unsatisfactory, and the adhesion strength between the two may be reduced significantly. Therefore, the softening point of the glass frit is specified to be within the range of 570° C. or higher, and 760° C. or lower.

Preferably, the lower limit of the softening point is 575° C. If the softening point is 575° C. or higher, the contact resistance can be reduced. A more preferable upper limit temperature of the softening point is 650° C. If the softening point is specified to be 650° C., the firing is conducted at lower temperatures.

Furthermore, a ratio, B₂O₃/SiO₂, is required to become 0.3 or less on a molar ratio basis. Preferably, the ratio is 0.2 or less, and in that case, Ag can be deposited on the semiconductor substrate efficiently.

The reason the above-described molar ratio of B₂O₃/SiO₂ is specified to be 0.3 or less is that the amount of Ag dissolved in the glass is reduced and deposit on the semiconductor substrate surface is easy during a firing step in the formation of a solar cell light-receiving surface electrode. It is believed that the contact between the light-receiving surface electrode and the semiconductor substrate is ensured by the Ag deposited. If the above-described molar ratio exceeds 0.3, Ag is dissolved in the glass stably and, thereby, deposition of Ag on the semiconductor substrate may become difficult.

Regarding the electrically conductive paste according to the present invention, Bi₂O₃ is not contained in the glass frit if the electrically conductive paste or even when Bi₂O₃ is contained, the content is within the range of less than 20.0 percent by mole. The reason the Bi₂O₃ content is specified to be 0.0 or more, and less than 20.0 percent by mole is that if the Bi₂O₃ content becomes 20.0 percent by mole or more, the viscosity of the glass becomes too low in the firing of the electrically conductive paste, excess glass is accumulated at the interface between the light-receiving surface electrode and the semiconductor substrate and, as a result, the glass may hinder the contact between the two significantly. On the other hand, in the case where 0.0 or more but less than 20.0 percent by mole of Bi₂O₃ is blended, excess glass is difficult to accumulate at the interface between the light-receiving surface electrode and the semiconductor substrate.

Furthermore, it is preferable that the glass frit further contains Al₂O₃, TiO₂, and CuO at ratios of Al₂O₃ of 15 percent by mole or less, TiO₂ of 10 percent by mole or less, and CuO of 15 percent by mole or less. By Al₂O₃, TiO₂, and CuO being blended at amounts within the above-described ranges, devitrification of the glass frit is reduced and, in addition, the water resistance of the glass frit itself can be enhanced. If the water resistance of the glass frit is enhanced, the moisture resistance of the electrode film is also enhanced when the electrically conductive paste is hardened.

Regarding the electrically conductive paste according to the present invention, in addition to the above-described Ag powder, organic vehicle, and the glass frit, appropriate additives may be further blended. Examples of such additives can include various inorganic powders. Examples of such inorganic powders can include inorganic oxides, e.g., ZnO, TiO₂, Ag₂O, WO₃, V₂O₅, Bi₂O₃, and ZrO₂. In the firing of the electrically conductive paste, these inorganic oxides operate to facilitate decomposition of the antireflection film formed on the semiconductor substrate surface in advance and reduce the contact resistance between the light-receiving surface electrode and the semiconductor substrate. It is believed that in the firing of the electrically conductive paste to form the light-receiving surface electrode, the Ag powder also operates as a catalyst for decomposing the antireflection film. In the case where a composition composed of the Ag powder, the organic vehicle, and the glass frit is used, removal of the antireflection film may become unsatisfactory. However, addition of the above-described inorganic oxide is desirable because the catalytic action of Ag is facilitated. Addition of ZnO, TiO₂, or ZrO₂, among the above-described inorganic oxides, is desirable because a higher effect of removing the antireflection film is exhibited. The average particle diameter of the additive composed of these inorganic oxides is not specifically limited. However, 1.0 μm or less is desirable. Addition of fine powders of such inorganic oxides enhances the catalytic action of Ag more effectively and can reduce the contact resistance between the light-receiving surface electrode and the semiconductor substrate more reliably and stably.

As for such additives, resonates containing metals or metal compounds may be used. As for the metal used for the resinate, at least one metal selected from Zn, Bi, and Ti or a metal compound thereof can be used. Addition of the metal or the metal compound in the form of the resinate into the electrically conductive paste can disperse the metal component more homogeneously as compared with that in the case where addition is conducted in the form of an inorganic powder and, therefore, the antireflection film can be decomposed more effectively. Furthermore, an electrically conductive paste is obtained in which aggregates resulting from poor dispersion in the paste are made finer and reduced. The use of the resulting electrically conductive paste can form a good printed film which does not easily cause plugging with respect to even a high mesh screen. Moreover, since sintering of the light-receiving surface electrode is not hindered, the light-receiving surface electrode can be densely fired, and the line resistance of the electrode can be reduced.

As for the above-described organic vehicle, an organic resin binder commonly used as in an electrically conductive paste for forming the light-receiving surface electrode can be used. Examples of synthetic resins constituting such an organic resin binder can include ethyl cellulose and nitrocellulose.

The electrically conductive paste is prepared by mixing the above-described Ag powder and the glass frit, dispersing the mixture into an organic vehicle solution in which an organic binder resin serving as an organic vehicle is dissolved in a solvent, and conducting kneading. Alternatively, the Ag powder, the organic vehicle, and the glass frit may be put into a solvent which dissolves the organic vehicle, and kneading may be conducted.

The blend ratios of individual components of the electrically conductive paste according to the present invention are not specifically limited. However, it is preferable that the ratio of the above-described glass frit is 1 to 3 parts by weight relative to 100 parts by weight of Ag powder. If the blend ratio of the glass frit is too large, the electrical conductivity becomes unsatisfactory. If the blend ratio of the glass frit is too small, the adhesion strength between the light-receiving surface electrode and the semiconductor substrate is not easily enhanced. The lower limit of the blend ratio of the above-described glass frit is preferably 1.5 parts by weight. The adhesion strength can be further enhanced by specifying the blend ratio to be 1.5 parts by weight or more. Furthermore, the preferable upper limit of the blend ratio of the above-described glass frit is 2.5 parts by weight. The contact resistance can be reduced by specifying the blend ratio to be 2.5 parts by weight or less.

The above-described organic vehicle is blended preferably at a ratio of about 20 parts by weight to 25 parts by weight relative to 100 parts by weight of Ag powder, although it not specifically limited. If the blend ratio of the organic vehicle is too large, conversion to a paste may become difficult, and if too low, it may become difficult to ensure a fine line property.

The blend ratio of the additive composed of the above-described inorganic oxide is not specifically limited. However, about 3 to 15 parts by weight relative to 100 parts by weight of Ag powder is desirable. If the blend ratio is less than 3 parts by weight, the effect of addition of the inorganic oxide may not be exerted satisfactorily. If the blend ratio exceeds 15 parts by weight, sintering of the Ag powder may be hindered and the line resistance may increase significantly.

The blend ratio of the above-described additive composed of the resinate is not specifically limited. However, about 8 to 16 parts by weight relative to 100 parts by weight of Ag powder is desirable. Most preferably, the blend ratios of the Zn resinate, the Ti resinate, and the Bi resinate are specified to be 8 parts by weight, 14 parts by weight, and 15 parts by weight, respectively.

As is clear from specific examples described later, the use of the electrically conductive paste containing the glass frit having the above-described specific composition can enhance the adhesion strength of the light-receiving surface electrode 3 to the semiconductor substrate 2 effectively and does not cause a significant increase in electrical resistance at contact interface between the two.

Consequently, even in the case where firing is conducted at low temperatures, a light-receiving surface electrode 3 exhibiting excellent reliability can be formed and, in addition, a reduction in cost of the solar cell and improvement of reliability can be achieved. Furthermore, since the glass frit does not contain Pb, the environmental load can be reduced.

Next, the present invention will be made clear by describing specific examples and comparative examples.

Regarding an electrically conductive paste, a plurality of types of electrically conductive pastes were prepared, in which 2.2 parts by weight of glass frit having a composition shown in Table 1 and 5 parts by weight of ZnO relative to 100 parts by weight of spherical Ag powder having an average particle diameter of 1 μm were mixed and, furthermore, 3.8 parts by weight of ethyl cellulose serving as a binder resin and terpineol serving as a solvent were contained. Subsequently, the above-described electrically conductive paste was screen-printed on a light-receiving surface on which a SiN antireflection film was formed entirely, of a polycrystalline silicon solar cell by using a pattern as shown in FIG. 3. In the pattern 11 shown in FIG. 3, print portions 11a to 11f indicate regions in which the electrically conductive paste is printed.

The distance between the print portions 11a and 11b was specified to be 200 μm, the distance between the print portions 11b and 11c was specified to be 400 μm, the distance between the print portions 11c and 11d was specified to be 600 μm, the distance between the print portions 11d and 11e was specified to be 800 μm, and the distance between the print portions 11e and 11f was specified to be 1,000 μm. Here, this distance between the print portions was specified to be the distance between an end edge of one print portion on the side of an end edge of the other print portion and the end edge of the other print portion on the side of the end edge of the one print portion.

After the above-described electrically conductive paste was printed, the electrically conductive paste was dried in an oven set at 150° C. Thereafter, the electrically conductive paste was fired in a near infrared furnace, in which the carrying time from inlet to outlet was about 4 minutes, on the basis of a firing profile in which a peak temperature was specified to be 750° C., so as to form a light-receiving surface electrode.

A cell for a solar cell provided with the light-receiving surface electrode as described above was used, and the contact resistance Rc was measured by a TLM (Transmission Line Model) method. The TLM method refers to a method in which the distances and the resistance values between light-receiving surface electrode portions formed in accordance with the print portions shown in FIG. 3 are measured, the relationship of the distance L between the electrode portions with the measured resistance value R is evaluated under various conditions because the relationship represented by the following Formula (1) holds between the distance L between the electrode portions and the measured resistance value R, and the contact resistance Rc is determined by extrapolating L to zero.

R=(L/Z)×RSH+2Rc Formula (1)

In Formula (1), R represents a measured resistance value, L represents a distance between the above-described electrode portions, RSH represents a sheet resistance of an n-type Si based semiconductor layer, Z represents a length of the light-receiving surface electrode, that is, a dimension corresponding to the length of the print portion shown in FIG. 3, and Rc represents a contact resistance.

The contact resistance Rc determined as described above is shown in the following Table 1.

In order to form a Ag electrode having the film thickness of 10 μm and a rectangle having the dimensions of 2×3 mm, the above-described electrically conductive paste was screen-printed on a light-receiving surface, on which a SiN antireflection film was formed, of a polycrystalline silicon solar cell. Subsequently, drying was conducted in an oven set at 150° C. Thereafter, firing was conducted by using a near infrared furnace on the basis of a firing profile in which it took about 4 minutes to pass between the inlet and the outlet and a peak temperature of 780° C., so as to form the above-described light-receiving surface electrode. Then, a copper wire was soldered to the light-receiving surface electrode surface so as to obtain a sample. Solder having a composition of Sn—Pb-1.5Ag was used as the solder, and soldering was conducted by dipping in the molten solder at 260° C. for 5 seconds.

An external force was applied in a direction of this copper wire being moved away from the solar cell substrate with a tensile tester. The peeling strength at the point in time when the light-receiving surface electrode was peeled off the semiconductor substrate of the solar cell was determined and was assumed to be the adhesion strength of the electrode to the semiconductor substrate. The results are shown in Table 1 described below.

The adhesion strength is evaluated because if the adhesion strength of the light-receiving surface electrode to the semiconductor substrate is low, the light-receiving surface electrode may be peeled off the semiconductor substrate when wiring of an inner lead for mutually connecting semiconductor substrates of the solar cell or in the case where a module is prepared thereafter. Therefore, as the adhesion strength becomes higher, such peeling can be prevented and the reliability can be enhanced.

TABLE 1

| | | | | | | | | | | | | | | B₂O₃/ | | | |
|---|---|---|---|---|---|---|---|---|---|---|---|---|---|---|---|---|---|
| | | | | | | | | | | | | | | SiO₂ | | | Adhesion |
| | Glass composition (mol %) | | | | | | | | | | | | | (mol % | Ts/ | Rc/ | strength |
| | SiO₂ | B₂O₃ | Bi₂O₃ | Li₂O | Na₂O | CaO | BaO | ZnO | Al₂O₃ | TiO₂ | ZrO₂ | CuO | Total | ratio) | ° C. | Ω | N/6 mm² |
| Example 1 | 54.7 | 12.7 | 13.6 | 0.0 | 0.0 | 0.0 | 18.5 | 0.0 | 5.5 | 4.6 | 0.0 | 2.1 | 100.0 | 0.23 | 611 | 2.6 | 2.4 |
| Example 2 | 49.9 | 14.5 | 0.0 | 0.0 | 0.0 | 4.7 | 22.5 | 1.9 | 2.8 | 1.3 | 2.4 | 0.0 | 100.0 | 0.29 | 754 | 1.3 | 2.0 |
| Example 3 | 49.5 | 4.5 | 18.0 | 0.0 | 0.0 | 0.0 | 18.0 | 0.0 | 9.9 | 0.0 | 0.0 | 0.0 | 100.0 | 0.09 | 614 | 1.8 | 2.7 |
| Example 4 | 52.2 | 13.0 | 17.4 | 0.0 | 0.0 | 0.0 | 17.4 | 0.0 | 0.0 | 0.0 | 0.0 | 0.0 | 100.0 | 0.25 | 597 | 1.8 | 3.6 |
| Example 5 | 43.3 | 11.8 | 19.7 | 0.0 | 0.0 | 0.0 | 15.8 | 0.0 | 9.5 | 0.0 | 0.0 | 0.0 | 100.0 | 0.27 | 575 | 1.9 | 3.4 |
| Example 6 | 51.1 | 12.8 | 17.0 | 0.0 | 0.0 | 0.0 | 17.0 | 0.0 | 0.0 | 2.1 | 0.0 | 0.0 | 100.0 | 0.25 | 605 | 2.1 | 2.6 |
| Example 7 | 56.7 | 15.0 | 13.6 | 0.0 | 0.0 | 0.0 | 0.0 | 0.0 | 10.0 | 4.7 | 0.0 | 0.0 | 100.0 | 0.26 | 611 | 2.6 | 2.5 |
| Example 8 | 47.1 | 13.7 | 5.7 | 0.0 | 0.0 | 4.4 | 21.2 | 1.8 | 2.6 | 1.2 | 2.3 | 0.0 | 100.0 | 0.29 | 703 | 2.4 | 2.1 |
| Comparative | 47.6 | 10.8 | 27.2 | 0.0 | 0.0 | 0.0 | 0.0 | 0.0 | 10.0 | 4.4 | 0.0 | 0.0 | 100.0 | 0.23 | 566 | 15.5 | 3.7 |
| example 1 | | | | | | | | | | | | | | | | | |
| Comparative | 36.8 | 19.4 | 0.0 | 3.5 | 3.9 | 3.6 | 13.4 | 12.9 | 4.4 | 0.8 | 1.3 | 0.0 | 100.0 | 0.53 | 606 | 34.9 | 2.9 |
| example 2 | | | | | | | | | | | | | | | | | |

As is clear from Table 1, the molar ratios B₂O₃/SiO₂ in Examples 1 to 8, are within the range of 0.29 or less and the softening point of the glass frits fall within the range of 570° C. to 760° C. and, therefore, the contact resistance Rc between the light-receiving surface electrode obtained by firing and the semiconductor substrate was a low 1.3 to 2.6Ω or less. Consequently, it is clear that good ohmic contact is achieved.

Furthermore, the adhesion strength between the light-receiving surface electrode formed from Ag and the semiconductor substrate tends to decrease as the softening point of the glass frit becomes higher. However, even in Example 2 in which the softening point was the highest among those in Examples 1 to 8, the adhesion strength was 2.0 N/6 mm². Therefore, it is clear that the adhesion strength is at a satisfactory level.

On the other hand, a glass frit having a molar ratio, B₂O₃/SiO₂, of 0.23 and a softening point of 566° C. was used in Comparative example 1 and a glass frit having the above-described molar ratio of 0.53 and a softening point of 606° C. was used in Comparative example 2. Consequently, the contact resistances Rc after firing were very high 15.5Ω and 34.9Ω, respectively.

That is, regarding Comparative example 1, it is believed that since the softening point of the glass frit is too low, and the glass, which is an insulating material, excessively accumulates at an interface between the light-receiving surface electrode formed from Ag and the semiconductor substrate and, thereby, the contact resistance increases. On the other hand, regarding Comparative example 2, it is believed that since the above-described molar ratio is 0.53 and the Ag powder dissolved in the glass is reduced on the surface of the semiconductor substrate formed from Si so as to become difficult to deposit during firing of the electrically conductive paste, the continuity between the light-receiving surface electrode and the semiconductor substrate is not ensured satisfactorily and, thereby, the contact resistance Rc becomes high.

Incidentally, in many cases where the light-receiving surface electrode of the solar cell is formed by the electrically conductive paste, the contact resistance cannot be satisfactorily stably reduced by merely applying and firing the electrically conductive paste. Consequently, a method in which an acid treatment is conducted to reduce the contact resistance between the light-receiving surface electrode and the semiconductor substrate has been adopted previously. In general, HF (hydrofluoric acid) is used for such an acid treatment. It is believed that if the acid treatment is conducted by using hydrofluoric acid, glass and oxides of Si present between the light-receiving surface electrode and the semiconductor substrate are dissolved and good contact between the light-receiving surface electrode and the semiconductor substrate is achieved. However, there is also a possibility that glass is dissolved and removed by HF. If glass and the like are excessively dissolved/removed, the adhesion strength between the light-receiving surface electrode and the semiconductor substrate may be reduced.

On the other hand, if the electrically conductive paste according to the present invention is used, the contact resistance Rc can be reduced satisfactorily without conducting such an acid treatment as shown in the above-described Examples. Consequently, the above-described problems due to the acid treatment do not occur easily and, in addition, an extra step, that is, the acid treatment step, can be omitted. Therefore, the production steps can be cut back.

1. An electrically conductive paste for forming a light-receiving surface electrode of a solar cell, the electrically conductive paste characterized by comprising a Ag powder, an organic vehicle, and glass frit, wherein the softening point of the glass frit is 570° C. to 760° C., the glass frit contains B₂O₃ and SiO₂ in such a way that a molar ratio, B₂O₃/SiO₂, is 0.3 or less and the glass frit contains less than 20 mole percent of Bi₂O₃.

2. The electrically conductive paste according to claim 1 in which the glass frit does not contain Bi₂O₃.

3. The electrically conductive paste according to claim 1, wherein the glass frit further comprises up to 15 percent by mole of Al₂O₃, up to 10 percent by mole of TiO₂, and up to 15 percent by mole of CuO.

4. The electrically conductive paste according to claim 3, further comprising at least one additive selected from the group consisting of ZnO, TiO₂, and ZrO₂ in addition to the glass frit.

5. The electrically conductive paste according to claim 1, further comprising at least one oxide or resinate of a metal selected from the group consisting of Zn, Bi, and Ti as an additive in addition to the glass frit.

6. The electrically conductive paste according to claim 5, in which the Ag has an average particle diameter of 0.1 to 15 μm, the glass frit has a softening point of 5575° C. to 650° C., the B₂O₃/Si₂O₃ molar ratio is 0.2 or less, and the oxide or resinate has an average particle diameter of 1 μm or less.

7. The electrically conductive paste according to claim 6, in which the glass frit is 1 to 3 weight parts, the vehicle is 20 to 25 weight parts and the additive is 3 to 15 weight parts when an oxide and 8 to 15 weight parts when a resinate per 100 parts of Ag.

8. The electrically conductive paste according to claim 6, in which the glass frit is 1.5 to 2.5 weight parts per 100 parts of Ag.

9. The electrically conductive paste according to claim 1, in which the Bi₂O₃ amount is greater than 0%.

10. The electrically conductive paste according to claim 9, wherein the glass frit further comprises up to 15 percent by mole of Al₂O₃, up to 10 percent by mole of TiO₂, and up to 15 percent by mole of CuO.

11. The electrically conductive paste according to claim 11, further comprising at least one additive selected from the group consisting of ZnO, TiO₂, and ZrO₂ in addition to the glass frit.

12. The electrically conductive paste according to claim 11, further comprising at least one resinate of a metal selected from the group consisting of Zn, Bi, and Ti as an additive in addition to the glass frit.

13. The electrically conductive paste according to claim 12, in which the Ag has an average particle diameter of 0.1 to 15 μm, the glass frit has a softening point of 575° C. to 650° C., the B₂O₃/Si₂O₃ molar ratio is 0.2 or less, and the oxide or resinate has an average particle diameter of 1 μm or less.

14. The electrically conductive paste according to claim 13, in which the glass frit is 1 to 3 weight parts, the vehicle is 20 to 25 weight parts and the additive is 3 to 15 weight parts when an oxide and 8 to 15 weight parts when a resinate per 100 parts of Ag.

15. The electrically conductive paste according to claim 14, in which the glass frit is 1.5 to 2.5 weight parts per 100 parts of Ag.

16. The electrically conductive paste according to claim 1, in which the molar ratio, B₂O₃/SiO₂, is 0.23 to 0.29.

17. A solar cell characterized by comprising a semiconductor substrate having two surfaces, a light-receiving surface electrode disposed on one surface of the semiconductor substrate, and a reverse surface electrode disposed on the other surface, wherein the light-receiving surface electrode is a film of baked electrically conductive paste according to claim 9.

18. A solar cell characterized by comprising a semiconductor substrate having two surfaces, a light-receiving surface electrode disposed on one surface of the semiconductor substrate, and a reverse surface electrode disposed on the other surface, wherein the light-receiving surface electrode is a film of baked electrically conductive paste according to claim 2.

19. A solar cell characterized by comprising a semiconductor substrate having two surfaces, a light-receiving surface electrode disposed on one surface of the semiconductor substrate, and a reverse surface electrode disposed on the other surface, wherein the light-receiving surface electrode is a film of baked electrically conductive paste according to claim 1.

20. A solar cell according to claim 19 in which the film of baked electrically conductive paste is disposed on less than all of the one surface of the semiconductor substrate and an anti-reflective film is disposed on the remaining portions of the one surface of the semiconductor substrate.
